(19) United States
(12) Patent Application Publication
(10) Pub. No.: US 2004/0173140 A1
(43) Pub. Date: Sep. 9, 2004

(54) Apparatus and method for balanced pressure growth of Group III-V monocrystalline semiconductor compounds

(76) Inventors: Xiao Gordon Liu, Fremont, CA (US); Morris Young, Fremont, CA (US)

Correspondence Address: DICKINSON WRIGHT PLLC, 1901 L. STREET NW, SUITE 800, WASHINGTON, DC, 20036, US

(21) Appl. No.: 10/378,991

(22) Filed: Mar. 5, 2003

(51) Int. Cl. C30B 9/00; C30B 11/00; C30B 17/00; C30B 21/02; C30B 28/06

(52) U.S. Cl. 117/81; 117/83

(57) ABSTRACT

An apparatus and a method for growth of Group III-V monocrystalline semiconductor compounds in a closed system with a balanced pressure maintained between the inside of a sealed ampoule and a pressure vessel. The vapor pressure inside the sealed ampoule can be controlled by temperature, the amount of polycrystalline charge and an amount of material such as phosphorus inside the sealed ampoule. Filling and release of an inert gas is used to control the pressure in the pressure vessel.

The present invention relates generally to the growth of semiconductor crystals. More particularly, the present invention relates to the high pressure growth of Group III-V monocrystalline semiconductor compounds.

### BACKGROUND OF THE INVENTION

Large diameter, highly pure, single crystal indium phosphide (InP) and other Group III-V compounds have become important materials for a wide variety of applications. InP crystal, in particular, is favored for use as a structural material in the fabrication of substrates used for lattice-matched fiber-optic sources and detectors, high speed integrated circuits, and high frequency microwave devices. However, it is difficult to grow large diameter single crystals of InP with high quality for successful use as good quality substrates for a thin film device in volume production.

Balanced pressure growth is particularly important during the various stages of InP crystal growth. In an open growth system such as Liquid-encapsulated-Czochralski (LEC), various conventional means to control the vapor have been employed. These controlling means often include the use of a thick boron oxide layer and high pressure. Nonetheless, volatile phosphorous is lost, resulting in poor stoichiometry control of the single crystals and poor yield. The low quality crystalline InP and poor yield leads to high cost in preparing these single crystals.

In closed systems for InP crystal growth, such as gradient freeze systems, explosion of the sealed ampoule due to the rapid change of the phosphorus vapor pressure is a major problem. Moreover, the phosphorus vapor pressure is difficult to control under the various conditions of crystal growth. The fluctuation in phosphorus vapor affects the solid-liquid interface in the growth region causing inhomogeneity of the stoichiometric composition. Accordingly, non-stoichiometric crystals result from the loss of volatile phosphorus during InP crystal growth, and small diameter crystal growth due to the use of thick-wall, small-bore quartz ampoules because of pressure considerations, are obtained.

Thus, controlling the exceptionally high vapor pressure of phosphorus at the melting temperature of the crystal is important in the growth of large diameter crystalling InP with uniform stoichiometry, and essential to overcome the deficiencies in conventional growth techniques.

### SUMMARY OF THE INVENTION

The present invention provides an apparatus and method for performing balanced pressure growth of Group III-V monocrystalline semiconductor compounds.

The present invention includes a crucible loaded with a crystal seed and a polycrystalline charge, and an ampoule, containing a material such as phosphorus, which is sealed to contain the crucible. A heating unit having a plurality of heating elements is disposed adjacent to the sealed ampoule, and a vessel contains the heating unit and the sealed ampoule. The vessel includes a gas inlet port, a gas relief port, and a pressure transducer to monitor a vessel pressure of the sealed ampoule and provide a vessel pressure signal. The vessel also includes a plurality of thermocouples to monitor the vessel temperature and to provide vessel temperature signals.

In one aspect of the present invention, the apparatus includes a temperature controller coupled to receive the vessel temperature signals from the thermocouples and to output a heater control signal and a temperature control signal. A signal conditioner is coupled to receive both the vessel pressure signal from the pressure transducer, and the temperature control signal from the temperature controller, and output a gas control signal according to a predetermined relationship between the vessel pressure signal and the temperature control signal. A motorized regulator is coupled to receive the gas control signal and regulate, responsive to the gas control signal, the filling of the vessel with an inert gas through the gas inlet port, and the releasing of the inert gas through the gas relief port of the vessel.

In one aspect of the present invention, a method of performing crystal growth of a Group III-V semiconductor crystal compound, includes: loading a crucible containing a crystal seed into an ampoule; sealing said ampoule; loading said sealed ampoule into a heating unit within a pressure vessel; increasing a temperature of said ampoule; and adjusting a vapor pressure within said pressure vessel according to a predetermined temperature-pressure relationship by filling and releasing an inert gas within said pressure vessel, such that a near zero differential pressure is maintained between said ampoule and said vessel over a temperature range of said crystal growth.

In another aspect of the present invention, a method of performing crystal growth of a Group III-V semiconductor crystal compound, includes loading a crucible with a crystal seed, boric oxide, and an InP polycrystalline charge; loading an ampoule with a predetermined amount of phosphorous; placing the crucible in the ampoule; sealing the ampoule containing the crucible, the sealed ampoule having a vapor pressure; providing a heating unit having a plurality of heating elements adjacent to the sealed ampoule; providing a vessel which contains the heating unit and the sealed ampoule, the vessel having a vessel temperature and a vessel pressure; activating the heating elements to cause: (a) an increase of the vessel temperature and the vessel pressure, and (b) heating and vaporization of the phosphorous to increase the vapor pressure of the sealed ampoule; monitoring the vessel temperature and the vessel pressure; and filling and releasing the vessel with an inert gas according to a predetermined relationship between the vessel temperature and the vessel pressure, thereby maintaining a balance between the vessel pressure and the vapor pressure.

In yet another aspect of the present invention, an apparatus for performing growth of Group III-V monocrystalline semiconductor compounds, includes: a crucible; an ampoule in which said crucible is disposed and sealed; a heating unit disposed adjacent to said ampoule; a pressure vessel in which said ampoule is disposed; and means for maintaining a near zero differential pressure between said sealed ampoule and said pressure vessel during crystal growth.

In yet another aspect of the present invention, an apparatus for performing growth of Group III-V monocrystalline semiconductor compounds, includes: a crucible; an ampoule in which said crucible is disposed and sealed; a heating unit disposed adjacent to said ampoule; a pressure vessel in which said ampoule is disposed, said pressure vessel having a means for determining pressure which outputs a vessel pressure signal; a temperature controller which controls said heating unit to cause a controlled temperature in said pressure vessel, said temperature controller outputting a temperature control signal; a signal conditioner which outputs a gas control signal according to a predetermined relationship between said temperature control signal and a vessel pressure signal; and a motorized regulator which regulates, in response to said gas control signal, filling and releasing of inert gas into said pressure vessel to maintain a predetermined pressure within said pressure vessel.

In yet another aspect of the present invention, an apparatus for performing growth of Group III-V monocrystalline semiconductor compounds, includes: a crucible; an ampoule sealed to contain the crucible, the sealed ampoule having a vapor pressure; a heating unit having a plurality of heating elements adjacent to the sealed ampoule; a vessel containing the heating unit and the sealed ampoule, the vessel having a gas inlet port, a gas relief port, and a pressure transducer to monitor a vessel pressure and provide a vessel pressure signal, the vessel including a plurality of thermocouples to monitor a vessel temperatures and provide vessel temperature signals; a temperature controller coupled to receive the vessel temperature signals from the thermocouples and output: (a) a heater control signal, and (b) a temperature control signal; a signal conditioner coupled to receive: (a) the vessel pressure signal from the pressure transducer, and (b) the temperature control signal from the temperature controller, the signal conditioner further coupled to output a gas control signal according to a predetermined relationship between the vessel pressure signal and the temperature control signal; and a motorized regulator coupled to receive the gas control signal and regulate, responsive to the gas control signal, filling and releasing of inert gas from an inert gas source through the gas inlet port and the gas relief port of the vessel.

In yet another aspect of the present invention, an apparatus for performing balanced pressure growth of Group III-V monocrystalline semiconductor compounds, comprising: a crucible; an ampoule sealed to contain the crucible, the sealed ampoule having a vapor pressure; a heating unit having a plurality of heating elements adjacent to the sealed ampoule; a vessel containing the heating unit and the sealed ampoule;

means for monitoring a vessel pressure; means for monitoring a vessel temperature; means for filling the vessel with an inert gas, when the vessel temperature increases, according to a predetermined relationship between the vessel temperature and the vessel pressure, thereby increasing the vessel pressure to maintain a balance between the vessel pressure and the vapor pressure.

In yet another aspect of the present invention, a method of performing crystal growth of a Group III-V semiconductor crystal compound, includes: loading a crucible containing a crystal seed into an ampoule; sealing said ampoule; loading said sealed ampoule into a heating unit within a pressure vessel; increasing a temperature of said ampoule; and adjusting a vapor pressure within said pressure vessel according to a predetermined temperature-pressure relationship by filling an inert gas within said pressure vessel, such that a predetermined differential pressure is maintained between said ampoule and said vessel over a temperature range of said crystal growth.

There has thus been outlined, some features consistent with the present invention in order that the detailed description thereof that follows may be better understood, and in order that the present contribution to the art may be better appreciated. There are, of course, additional features consistent with the present invention that will be described below and which will form the subject matter of the claims appended hereto.

In this respect, before explaining at least one embodiment consistent with the present invention in detail, it is to be understood that the invention is not limited in its application to the details of construction and to the arrangements of the components set forth in the following description or illustrated in the drawings. Methods and apparatuses consistent with the present invention are capable of other embodiments and of being practiced and carried out in various ways. Also, it is to be understood that the phraseology and terminology employed herein, as well as the abstract included below, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the methods and apparatuses consistent with the present invention.

### BRIEF DESCRIPTION OF THE DRAWINGS

FIG. 1 is a schematic diagram showing a cross-section of an exemplary system for performing balanced pressure growth of Group III-V monocrystalline semiconductor compounds, in accordance with one embodiment consistent with the present invention; and

FIG. 2 is a schematic diagram showing a cross-section of the interior of a vessel for balanced pressure growth of Group III-V monocrystalline semiconductor compounds, in accordance with one embodiment consistent with the present invention.

### DETAILED DESCRIPTION OF THE PREFERRED EMBODIMENTS

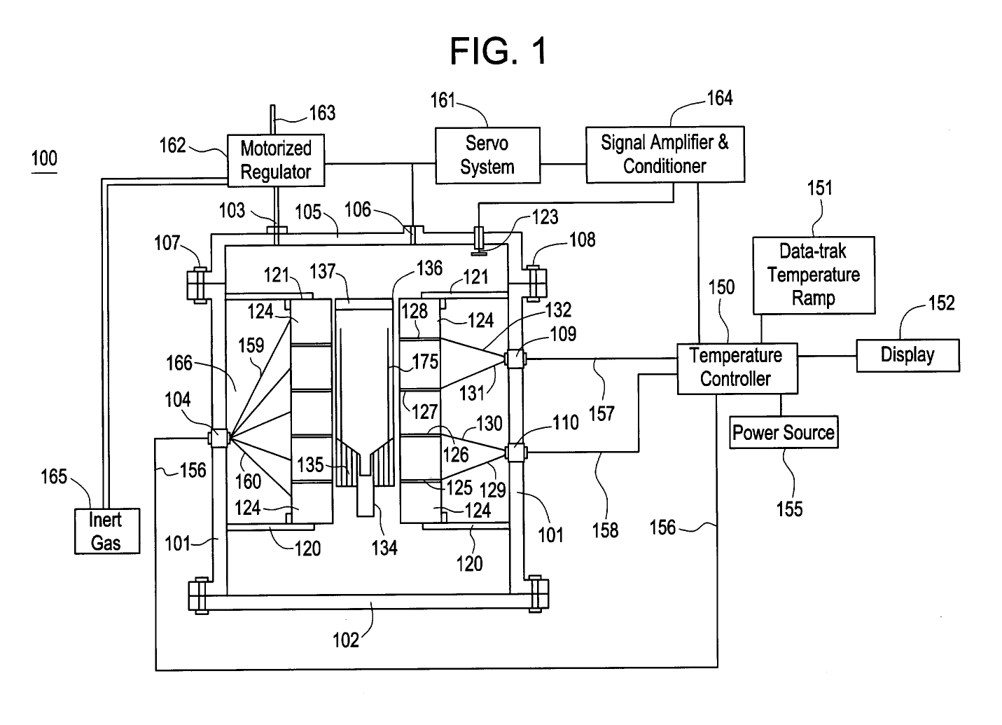

In FIG. 1, a balanced pressure growth system 100 is described in the context of a Vertical Gradient Freeze (“VGF”) apparatus. The system 100 includes a crucible 175 in which a Group III-V monocrystalline semiconductor compound (“crystal”) can be grown. For growth of InP crystals, the crucible 175 is loaded with a crystal seed, boron oxide (B₂O₃), and an InP polycrystalline charge (collectively, “process materials”). The amount of InP polycrystalline charge is preferably greater than about 5 kilograms. The crucible 175 is preferably oriented in a vertical position and is composed of material which does not react with the process materials, such as pyrolytic boron nitride (PBN). The crucible 175 also has a wall thickness selected to promote desired heat flow and mechanical strength, for example, greater than about 0.1 millimeters (mm).

In FIG. 1, an ampoule 136, preferably made of quartz, is loaded with a predetermined amount of phosphorous. As used herein, the terms “quartz,” “fused quartz,” and “fused silica” are used interchangeably, and include either natural quartz or any type of synthetic quartz made by fusing silica (SiO₂). An appropriate amount of phosphorus is selected for ampoule 136 to yield the desired vapor pressure at a stoichiometric InP melting temperature, as explained below. In one example, the amount of phosphorous is greater than about 20 grams. The ampoule 136 typically has a wall thickness greater than about 1 mm, preferably in the range of about 3 mm to 6 mm. The crucible 175 is inserted in the ampoule 136, as shown in FIG. 1. After inserting the phosphorous and crucible 175, the ampoule 136 is sealed with a quartz plug 137. The ampoule 136 is supported by an ampoule support 135.

In FIG. 1, the system 100 further includes a heating unit having an array of heating elements 124 situated adjacent to the sealed ampoule 136. The heating elements 124 are preferably shaped as rings disposed around and vertically adjacent to the ampoule 175. The heating unit is mounted on heater supports 120, 121 and is controlled to provide heating of the ampoule 136 and contents of the crucible 175 in a desired heat pattern.

A shown in FIG. 1, the system 100 further includes an outer pressure vessel (“vessel”) 166 which contains the heating unit and sealed ampoule 136. The vessel 166 includes a water-cooled cylindrical stainless steel housing 101, base 102, cover 105, and bolts 107, 108. The vessel 166 is equipped with a variety of control functions to maintain a near zero differential pressure between the sealed ampoule 136 and vessel 166 during the crystal growth process. The vessel 166 may also be equipped with a gas input port 103, a gas relief port 106, and an emergency vent 163 to balance the pressure by filling and releasing of an inert gas.

A desired vapor pressure inside the sealed ampoule 136 is determined according to phase equilibra and vapor pressure data. The vapor pressure is controlled as described below. A balance is then maintained between the vapor pressure and the pressure of the vessel (“vessel pressure”). The differential pressure is held near zero during temperature ramping in the crystal growth process.

As shown in FIG. 1, the vessel 166 includes a plurality of thermocouples 125-128, each situated between a respective pair of heating elements 124. Each thermocouple outputs a vessel temperature signal representing a vessel temperature measurement at the particular location of that thermocouple along the length of ampoule 136. Thermocouple conductors 129-132 receive the vessel temperature signals and provide the signals to thermocouple ports 109, 110 in housing 101. Thermocouple cable 157 carries the signals from conductors 131, 132, and cable 158 carries the signals from conductors 129, 130 to a temperature controller 150.

Temperature controller 150 receives the vessel temperature signals from the thermocouples and outputs both a heater control signal and a temperature control signal. The heater control signal is delivered from the temperature controller 150 to the heating elements 124 over power cables 156, 159, 160. In this way, temperature controller 150 can control the heating elements 124. The heating elements 124 can be activated in a controlled manner to cause a controlled increase of the vessel temperature, and deactivated to cause a controlled decrease of the vessel temperature. One example of a suitable temperature controller 150 is the UDC 1500 made by Honeywell. Other devices providing the same or similar functionality, while possibly having slight deviations or modifications, are also acceptable as will be understood by those skilled in the art. The temperature controller 150 is powered by a power source 155 such as the Eurotherm TC1027, TC1028, or TE200S.

In FIG. 1, a signal conditioner 164 is coupled to receive a vessel pressure signal from a pressure transducer 123 of vessel 166. This transducer 123 is formed as part of vessel 166. A suitable transducer 123 is the PX92-MV made by Omega, although other transducers can be used as should be understood by those skilled in the art. The signal conditioner 164 is also coupled to receive the temperature control signal from the temperature controller 150. The signal conditioner 164 outputs a gas control signal as a function of the two inputs. More specifically, the gas control signal is generated according to a predetermined relationship maintained by the conditioner 164 between the vessel pressure signal and the temperature control signal. One example of a suitable signal conditioner 164 is a DRA-ACT-4 Series device made by Omega. Other equivalent signal amplifiers and conditioners can be used in place of DRA-ACT-4 devices, as will be understood by those skilled in the art. Preferred devices are those that convert the measured input signals into a proportional, linear and highly accurate output current. The signal conditioner 164 also isolates the input from the output, thus enabling the conditioner 164 to withstand large momentary inputs.

In FIG. 1, a servo system 161 and motorized regulator 163 are coupled to receive the gas control signal from the signal conditioner 164. In one example, the servo system is an EA series device made by Eurotherm, and the motorized regulator 163 is the UP6 device made by Praxair. Other servo systems and motorized regulators can be used, as will be understood by those skilled in the art. The servo system 161 and motorized regulator 163 are sometimes referred to herein, collectively, as “motorized regulator.” The motorized regulator regulates, responsive to the gas control signal, the filling and releasing of inert gas from an inert gas source 165 through the gas inlet port 103 and the gas relief port 106 of the vessel 166. The gas source 165 can be any suitable source of inert gas such as the Praxair GC 401. Other alternative gas sources can be used, as will be understood by the skilled artisan.

In FIG. 1, a DATA-TRAK temperature ramp device 151 and display device 152 are coupled to temperature controller 150. One example of a suitable combination of ramp device 151 and display device 152 is the PC 3000 made by Eurotherm. The temperature ramp device 151 provides integrated analog and digital sequencing control. The ramp device 151 provides system control, monitoring, and sequencing of the analog and digital I/O of the growth system 100. The display device 152 provides an operator interface.

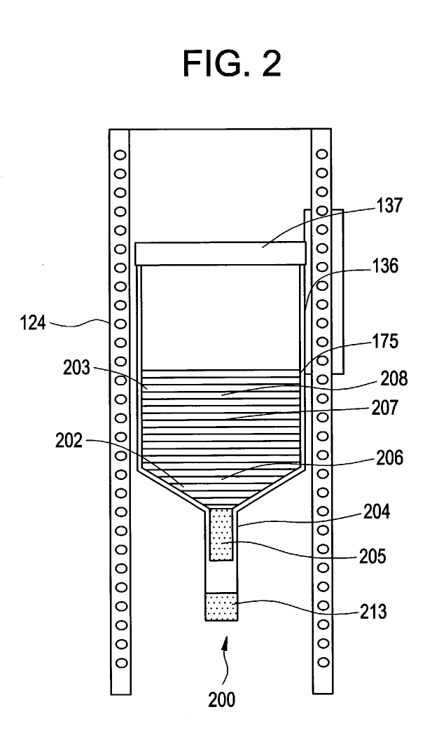

FIG. 2 shows the elemental phosphorus 213 placed in the bottom of the quartz ampoule 136. The polycrystalline InP charge and an appropriate amount of boron oxide (B₂0₃) are loaded into the growth crucible 175. The crystal seed 205 is positioned in the seed well 204. The crucible 175 also has a conical transition region 202 and a major growth region 203. The growth crucible 175 containing the charge, B₂0₃ and seed 205 is then loaded into the quartz ampoule 136. The quartz ampoule 136 is evacuated, preferably to ˜10⁻⁷ torr, by shrinking the open end of the ampoule 136 around a quartz plug 137 with a torch to seal the ampoule 136.

In FIG. 2, the addition of B₂0₃ in sufficient amount is used as a spacer layer between the molten InP and the crucible 175. Excess phosphorus in a predetermined amount is added to maintain a vapor pressure approximately 27.5 atm. at the stoichiometric InP melting temperature of 1062° C. With the prescribed vapor pressure, loss of volatile phosphorus during crystal growth is minimized. As a result, larger diameter stoichiometric InP crystals are grown.

In the balanced pressure growth process, the sealed quartz ampoule 136 is loaded into the heating unit, as shown in FIGS. 1 and 2. The heating unit has multiple heating elements 124 which are individually controlled by temperature controller 150 over power line 156. The temperature controller 150 supplies power to the heating elements to raise the vessel temperature and melt the polycrystalline InP charge in major growth region 203, as shown in FIG. 2. Temperature controller 150 in FIG. 1 monitors the temperature in the vessel 166. In FIG. 1, as the vessel temperature increases, the phosphorus inside the sealed quartz ampoule 136 is heated and vaporizes, exerting vapor pressure on the inside of the sealed quartz ampoule 136. The vapor pressure inside the sealed ampoule can be controlled by the amount of phosphorus loaded into the ampoule, temperature, and the amount of polycrystalline charge in the crucible. The vapor pressure inside the sealed ampoule is preferably ˜30 atmospheres. During this temperature ramp-up stage, the pressure in the pressure vessel 166 is adjusted by signal conditioner 164 according to the predetermined temperature-pressure relationship by activating the motorized regulator 162 to fill the vessel 166 with inert gas from source 165.

After the crystal growth process is complete, power to the heating elements 124 is reduced, so that the vessel temperature is reduced. The temperature controller 150, signal conditioner 164, and motorized regulator 163 correlate this temperature ramp-down to a vessel pressure reduction by releasing the inert gas in the high-pressure vessel according to the predetermined temperature-pressure relationship through the gas relief port 106 and the vent 163. In this way, a near zero differential pressure is maintained between the sealed quartz ampoule 136 and the vessel 166 over the entire temperature range of the crystal growth process.

When the growth system 100 reaches room temperature, the quartz ampoule 136 is removed and cracked open. Excessive phosphorus is burned off into the air. The crucible 175 containing the crystal is submerged in methanol to dissolve the B₂0₃. The crystal is separated from the growth crucible.

Due to the high vapor pressure of phosphorus over the stoichiometric InP at its melting point, equalizing the vessel pressure according to the temperature ramp rate, as described above, has the advantage of preventing ampoule explosion and providing for precise control of a liquid-solid interface 207, as shown in FIG. 2, between the crystallized material 206 and the melted charge 208.

It should be emphasized that the above-described embodiments of the invention are merely possible examples of implementations set forth for a clear understanding of the principles of the invention. Variations and modifications may be made to the above-described embodiments of the invention without departing from the spirit and principles of the invention. All such modifications and variations are intended to be included herein within the scope of the invention.

What is claimed is:

1. A method of performing crystal growth of a Group III-V semiconductor crystal compound, comprising:
loading a crucible containing a crystal seed into an ampoule;
sealing said ampoule;
loading said sealed ampoule into a heating unit within a pressure vessel;
increasing a temperature of said ampoule; and
adjusting a vapor pressure within said pressure vessel according to a predetermined temperature-pressure relationship by filling and releasing an inert gas within said pressure vessel, such that a near zero differential pressure is maintained between said ampoule and said vessel over a temperature range of said crystal growth.

2. The method of claim 1, further comprising:
depositing phosphorous into said ampoule.

3. The method of claim 1, wherein said ampoule is made of quartz.

4. The method of claim 2, further comprising:
depositing polycrystalline InP and boron oxide into said ampoule.

5. The method of claim 4, further comprising:
evacuating said ampoule to about 1×10⁻⁷ torr before said sealing step.

6. The method of claim 4, wherein said boron oxide is used as a spacer layer between said InP after it is heated and molten, and said crucible.

7. The method of claim 2, further comprising:
providing said phosphorous in a predetermined amount to maintain a vapor pressure of about 27.5 atm at the stoichiometric InP melting temperature of 1062° C.

8. The method of claim 1, wherein said heating unit is comprised of a plurality of multiple heating elements.

9. The method of claim 8, wherein said heating elements are individually controlled.

10. The method of claim 1, further comprising:
monitoring a temperature within said pressure vessel.

11. The method of claim 1, wherein said vapor pressure within said sealed ampoule is about 30 atmospheres.

12. The method of claim 1, wherein a regulator is used to activate filling of said pressure vessel.

13. The method of claim 12, further comprising:
adjusting said vapor pressure according to said predetermined temperature-pressure relationship by activating said regulator.

14. The method of claim 12, further comprising:
releasing said inert gas into said pressure vessel when a temperature of said pressure vessel is reduced.

15. A method of performing crystal growth of a Group III-V semiconductor crystal compound, comprising:
loading a crucible with a crystal seed, boric oxide, and an InP polycrystalline charge;
loading an ampoule with a predetermined amount of phosphorous;
placing the crucible in the ampoule;
sealing the ampoule containing the crucible, the sealed ampoule having a vapor pressure;
providing a heating unit having a plurality of heating elements adjacent to the sealed ampoule;
providing a vessel which contains the heating unit and the sealed ampoule, the vessel having a vessel temperature and a vessel pressure;
activating the heating elements to cause:
(a) an increase of the vessel temperature and the vessel pressure, and
(b) heating and vaporization of the phosphorous to increase the vapor pressure of the sealed ampoule;
monitoring the vessel temperature and the vessel pressure; and
filling and releasing the vessel with an inert gas according to a predetermined relationship between the vessel temperature and the vessel pressure, thereby maintaining a balance between the vessel pressure and the vapor pressure.

16. The method of claim 15, wherein the balance maintained between the vessel pressure and the vapor pressure is a near zero differential pressure.

17. The method of claim 15, wherein at least one of the crystal seed and the InP polycrystalline charge yields a vapor pressure of greater than about 5 atmospheres at a melting temperature of the InP semiconductor crystal compound.

18. An apparatus for performing growth of Group III-V monocrystalline semiconductor compounds, comprising:
a crucible;
an ampoule in which said crucible is disposed and sealed;
a heating unit disposed adjacent to said ampoule;
a pressure vessel in which said ampoule is disposed; and
means for maintaining a near zero differential pressure between said sealed ampoule and said pressure vessel during crystal growth.

19. An apparatus for performing growth of Group III-V monocrystalline semiconductor compounds, comprising:
a crucible;
an ampoule in which said crucible is disposed and sealed;
a heating unit disposed adjacent to said ampoule;
a pressure vessel in which said ampoule is disposed, said pressure vessel having a means for determining pressure which outputs a vessel pressure signal;
a temperature controller which controls said heating unit to cause a controlled temperature in said pressure vessel, said temperature controller outputting a temperature control signal;
a signal conditioner which outputs a gas control signal according to a predetermined relationship between said temperature control signal and a vessel pressure signal; and
a motorized regulator which regulates, in response to said gas control signal, filling and releasing of inert gas into said pressure vessel to maintain a predetermined pressure within said pressure vessel.

20. An apparatus for performing growth of Group III-V monocrystalline semiconductor compounds, comprising:
a crucible;
an ampoule sealed to contain the crucible, the sealed ampoule having a vapor pressure;
a heating unit having a plurality of heating elements adjacent to the sealed ampoule;
a vessel containing the heating unit and the sealed ampoule, the vessel having a gas inlet port, a gas relief port, and a pressure transducer to monitor a vessel pressure and provide a vessel pressure signal, the vessel including a plurality of thermocouples to monitor a vessel temperatures and provide vessel temperature signals;
a temperature controller coupled to receive the vessel temperature signals from the thermocouples and output: (a) a heater control signal, and (b) a temperature control signal;
a signal conditioner coupled to receive: (a) the vessel pressure signal from the pressure transducer, and (b) the temperature control signal from the temperature controller, the signal conditioner further coupled to output a gas control signal according to a predetermined relationship between the vessel pressure signal and the temperature control signal; and
a motorized regulator coupled to receive the gas control signal and regulate, responsive to the gas control signal, filling and releasing of inert gas from an inert gas source through the gas inlet port and the gas relief port of the vessel.

21. The apparatus of claim 20, further comprising:
a temperature ramp monitor coupled to the temperature controller to monitor the vessel temperature signals.

22. The apparatus of claim 19, wherein said crucible is loaded with a crystal seed, boron oxide, and an InP polycrystalline charge.

23. The apparatus of claim 22, wherein said InP polycrystalline charge is greater than about 5 kilograms.

24. The apparatus of claim 19, wherein said crucible is composed of pyrolytic boron nitride.

25. The apparatus of claim 19, wherein a wall thickness of said crucible is greater than about 0.1 mm.

26. The apparatus of claim 19, wherein said ampoule is made of quartz.

27. The apparatus of claim 26, wherein a predetermined amount of phosphorous is disposed in said ampoule.

28. The apparatus of claim 27, wherein said predetermined amount is selected to yield a desired vapor pressure at the stoichiometric InP melting temperature.

29. The apparatus of claim 19, wherein said ampoule has a wall thickness of greater than 1 mm.

30. The apparatus of claim 29, wherein said ampoule has a wall thickness between 2 mm and 6 mm.

31. The apparatus of claim 19, wherein said heating unit includes an array of heating elements.

32. The apparatus of claim 31, wherein said heating elements are individually controlled by said temperature controller.

33. The apparatus of claim 32, wherein said heating elements are disposed in said vessel such that said heating elements provide a desired heat pattern to said ampoule.

34. The apparatus of claim 19, wherein said pressure determining means is a pressure transducer.

35. The apparatus of claim 19, wherein said pressure vessel includes a gas input port, a gas relief port, and an emergency vent to balance said pressure by filling and releasing said inert gas.

36. The apparatus of claim 19, wherein a differential pressure between said pressure vessel and said ampoule during crystal growth is near zero.

37. The apparatus of claim 19, wherein said motorized regulator comprises a servo system and a motorized regulator.

38. An apparatus for performing balanced pressure growth of Group III-V monocrystalline semiconductor compounds, comprising:
a crucible;
an ampoule sealed to contain the crucible, the sealed ampoule having a vapor pressure;
a heating unit having a plurality of heating elements adjacent to the sealed ampoule;
a vessel containing the heating unit and the sealed ampoule;
means for monitoring a vessel pressure;
means for monitoring a vessel temperature;
means for filling the vessel with an inert gas, when the vessel temperature increases, according to a predetermined relationship between the vessel temperature and the vessel pressure, thereby increasing the vessel pressure to maintain a balance between the vessel pressure and the vapor pressure.

39. The apparatus of claim 38, further comprising:
means for releasing the inert gas from the vessel when the vessel temperature decreases, according to the predetermined relationship between the vessel temperature and the vessel pressure, thereby decreasing the vessel pressure to maintain a balance between the vessel pressure and the vapor pressure.

40. A method of performing crystal growth of a Group III-V semiconductor crystal compound, comprising:
loading a crucible containing a crystal seed into an ampoule;
sealing said ampoule;
loading said sealed ampoule into a heating unit within a pressure vessel;
increasing a temperature of said ampoule; and
adjusting a vapor pressure within said pressure vessel according to a predetermined temperature-pressure relationship by filling an inert gas within said pressure vessel, such that a predetermined differential pressure is maintained between said ampoule and said vessel over a temperature range of said crystal growth.

41. The method of claim 40, further comprising:
decreasing a temperature of said ampoule; and
releasing said inert gas from said pressure vessel to adjust said vapor pressure when a temperature of said ampoule decreases.
